(19) United States
(12) Patent Application Publication
(10) Pub. No.: US 2018/0190490 A1
(43) Pub. Date: Jul. 5, 2018

(54) THIN FILM TRANSISTOR AND METHOD FOR FABRICATING THE SAME

(71) Applicants: BOE Technology Group Co., Ltd., Beijing (CN); Ordos Yuansheng Optoelectronics Co., Ltd., Inner Mongolia (CN)

(72) Inventors: Mingchao MA, Beijing (CN); Jun FAN, Beijing (CN); Fuqiang LI, Beijing (CN)

(21) Appl. No.: 15/718,191

(22) Filed: Sep. 28, 2017

(30) Foreign Application Priority Data
Dec. 29, 2016 (CN) 201611247423.9

(51) Int. Cl. H01L 21/02; H01L 29/786; H01L 29/66; H01L 21/324; H01L 21/306; H01L 21/285; H01L 29/45; H01L 21/3205

(52) U.S. Cl. CPC H01L 21/02672; H01L 29/78603; H01L 29/66765; H01L 21/02532; H01L 21/02592; H01L 21/32051; H01L 21/30604; H01L 21/2855; H01L 29/458; H01L 29/78678; H01L 21/324

(57) ABSTRACT

Disclosed are a thin film transistor and a method for fabricating the same, where annealing can be performed on a base substrate formed with a metal inductive layer to thereby perform metal induced crystallization so as to fabricate the bottom-gate low-temperature poly-silicon thin film transistor while dispensing with a shielding layer in a top-gate thin film transistor. Furthermore an amorphous-silicon layer can be converted into a poly-silicon layer due to metal induced crystallization, and the patterning process can be further performed on the poly-silicon layer to form a first doped zone corresponding to an active layer, and a second doped zone corresponding to a source and drain area, so that a channel area can be separated from the source and drain area to thereby guarantee the electrical performance of the thin film transistor.

### CROSS-REFERENCE TO RELATED APPLICATION

This application claims priority of Chinese Patent Application No. 201611247423.9, filed on Dec. 29, 2016, which is hereby incorporated by reference in its entirety.

### FIELD

The present disclosure relates to the field of display technologies, and particularly to a thin film transistor and a method for fabricating the same.

### BACKGROUND

A Liquid Crystal Display (LCD), an Electro-Luminescence (EL) display panel, an electronic paper, and other display devices have been well known at present. The respective display devices include Thin Film Transistors (TFTs) for controlling respective pixels to be switched on and off. Generally as illustrated in FIG. 1, the structure of a thin film transistor generally includes a shielding layer 1, a buffer 2, an active layer 3, a gate insulation layer 4, a gate 5, a source 6, and a drain 7 on a base substrate, where the active layer is made of a poly-silicon material, the shielding layer is configured to shield light rays for affecting the poly-silicon material from the outside to thereby prevent the active layer from producing light-induced carriers so as to avoid a switching characteristic of the thin film transistor from being affected.

### SUMMARY

Some embodiments of the disclosure provide a method for fabricating a thin film transistor, the method includes: forming a buffer layer, a gate, and a pattern of a gate insulation layer on a base substrate in that order, the method further includes: forming an amorphous-silicon layer on the base substrate formed with the pattern of the gate insulation layer; forming a metal inductive layer on the base substrate formed with the amorphous-silicon layer; performing annealing on the base substrate formed with the metal inductive layer; performing a patterning process on the annealed base substrate to form a first doped zone corresponding to the active layer, and a second doped zone corresponding to a source and a drain; etching the formed first doped zone to form a pattern of the active layer; and forming patterns of the corresponding source and drain in the formed second doped zone.

Some embodiments of the disclosure provide a thin film transistor including comprising: a buffer layer, a gate, and a pattern of a gate insulation layer which are formed successively on a base substrate, wherein the thin film transistor further includes: an amorphous-silicon layer formed on the base substrate formed with the pattern of the gate insulation layer; a metal inductive layer formed on the base substrate formed with the amorphous-silicon layer; a first doped zone corresponding to an active layer, and a second doped zone corresponding to a source and a drain; a pattern of the active layer formed by etching the first doped zone; and patterns of the source and the drain formed in the second doped zone; the first doped zone and the second doped zone are formed by performing annealing on the base substrate formed with the metal inductive layer and performing a patterning process on annealed base substrate.

### BRIEF DESCRIPTION OF THE DRAWINGS

FIG. 1 is a schematic structural diagram of a related thin film transistor;

FIG. 2 is a flow chart of a method for fabricating a thin film transistor according to some embodiments of the disclosure; and

FIG. 3A to FIG. 3I are schematic diagrams of a process of fabricating a thin film transistor according to some embodiments of the disclosure.

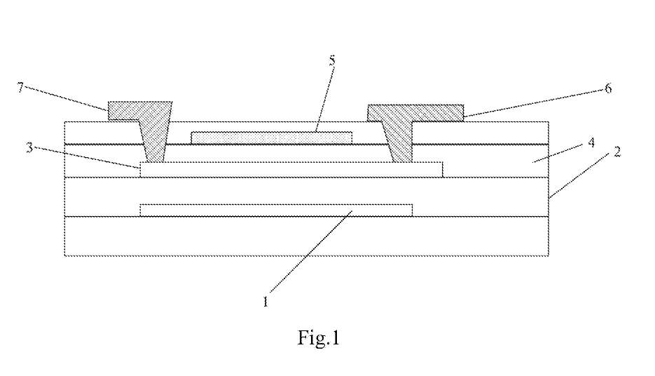

### DETAILED DESCRIPTION OF THE EMBODIMENTS

A thin film transistor and a method for fabricating the thin film transistor according to embodiments of the disclosure will be described below in details with reference to the drawings.

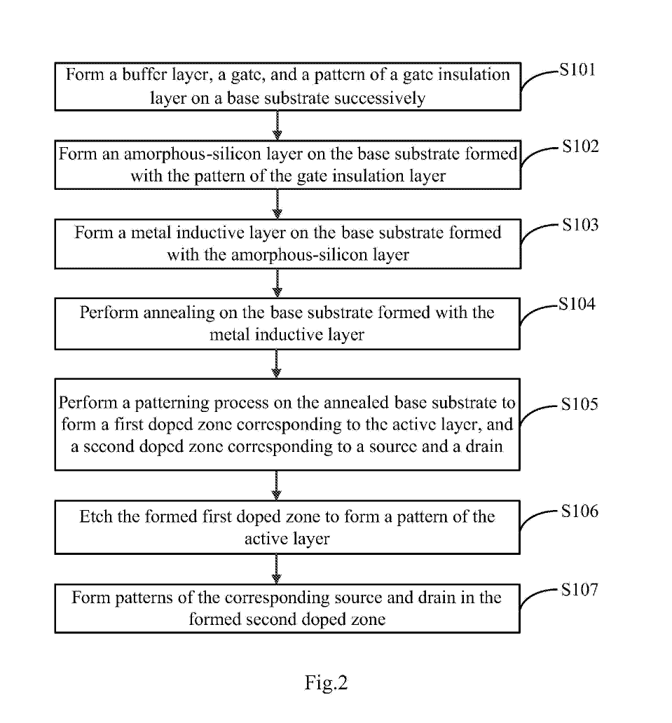

As illustrated in FIG. 2, some embodiments of the disclosure provide a method for fabricating a thin film transistor, where the method can include the following steps.

The step S101 is to form a buffer layer, a gate, and a pattern of a gate insulation layer on a base substrate successively;

The step S102 is to form an amorphous-silicon layer on the base substrate formed with the pattern of the gate insulation layer;

The step S103 is to form a metal inductive layer on the base substrate formed with the amorphous-silicon layer;

The step S104 is to perform annealing on the base substrate formed with the metal inductive layer;

The step S105 is to perform a patterning process on the annealed base substrate to form a first doped zone corresponding to the active layer, and a second doped zone corresponding to a source and a drain;

The step S106 is to etch the first doped zone to form a pattern of the active layer;

The step S107 is to form patterns of the corresponding source and drain in the second doped zone.

In the method above for fabricating a thin film transistor according to embodiments of the disclosure, annealing can be performed on the base substrate formed with the metal inductive layer to thereby perform metal induced crystallization so as to fabricate the low-temperature poly-silicon thin film transistor with bottom gate while dispensing with a shielding layer in a top-gate thin film transistor, thus saving the fabrication cost, simplifying the fabrication process, and dispensing with the step of doping the poly-silicon material due to metal induced crystallization. Furthermore the amorphous-silicon can be converted into the poly-silicon due to metal induced crystallization, and the patterning process can be further performed on the poly-silicon to form the first doped zone corresponding to the active layer, and the second doped zone corresponding to a source and drain area, so that a channel area can be separated from the source and drain area to thereby guarantee the electrical performance of the thin film transistor; and furthermore the first doped zone can be etched to thereby remove metal particles remaining in the channel area due to metal induced crystallization so as to reduce the off-stage current in the device, thus addressing the problem of the remaining metal particles, and guaranteeing the good electrical performance of the device.

In an implementation, in the method above for fabricating a thin film transistor according to embodiments of the disclosure, the step S104 can include: heating the base substrate formed with the metal inductive layer at preset heating temperature in a protective gas or vacuum atmosphere for a preset length of time, and thereafter cooling the base substrate naturally to indoor temperature, where the preset temperature can range from 400 to 600 □, and the preset length of time can range from 10 to 20 minutes. Optionally in the method above for fabricating a thin film transistor according to embodiments of the disclosure, the metal inductive layer can be deposited on the base substrate formed with the amorphous-silicon layer through a magnetron sputtering, where the material of the metal inductive layer can be one or a combination of aluminum, copper, nickel, gold, silver, or molybdenum. After the metal inductive layer is deposited, annealing is performed on the base substrate at annealing temperature ranging from 400 to 600° C. for 10 to 20 minutes to thereby convert the amorphous-silicon into the poly-silicon due to metal induced crystallization. Moreover the step of doping the poly-silicon layer can be left out due to metal induced crystallization.

In an implementation, in the method above for fabricating a thin film transistor according to embodiments of the disclosure, the step S106 can include: etching off a peak layer on the surface of the first doped zone to form the pattern of the active layer, where the peak layer is a metal layer doped on the surface of the first doped zone at a dosage of metal ions above a preset threshold; and an orthographic projection of the active layer onto the base substrate overlaps with an orthographic projection of the gate onto the base substrate. Optionally the patterning process can be performed on the poly-silicon layer after metal induced crystallization to form the first doped zone corresponding to the active layer, and the second doped zone corresponding to the source and the drain; and the etching process can be performed on the first doped zone to etch off the metal ions remaining in the first doped zone due to metal induced crystallization so as to alleviate leakage current in the channel area. In the etching process, since different gas is produced from different materials, the extent of etching can be guaranteed by detecting the type of gas; or the depth of etching can be controlled according to a relationship between the thickness of film layer and the etching period of time so that the entire peak layer at the higher doping concentration of metal ions can be etched off by etching in the first doped zone.

In an implementation, in the method above for fabricating a thin film transistor according to embodiments of the disclosure, the step S107 can include: deposing a source and drain metal layer on the base substrate formed with the second doped zone through a magnetron sputtering; and performing a patterning process on the source and drain metal layer to form the patterns of the source and the drain. Optionally the source and drain metal layer can be deposited on the base substrate formed with the second doped zone through the magnetron sputtering, and the patterning process can be further performed on the source and drain metal layer to form the corresponding source and drain. Furthermore there are metal ions doped in the second doped zone corresponding to the source and the drain, which is formed by performing the patterning process on the poly-silicon layer after metal induced crystallization, so the second doped zone can function for ohm contact between the source and the drain and the active layer, thus dispensing with the step of striping the metal inductive layer after metal induced crystallization.

In an implementation, in the method above for fabricating a thin film transistor according to embodiments of the disclosure, the source can be structured in a stack of titanium-aluminum-titanium or molybdenum-aluminum-molybdenum layers; and the drain can al so be structured in a stack of titanium-aluminum-titanium or molybdenum-aluminum-molybdenum layers. Optionally in the method above for fabricating a thin film transistor according to embodiments of the disclosure, a stack of titanium-aluminum-titanium or molybdenum-aluminum-molybdenum layers can be deposited as the source and drain metal layer, and a patterning process can be further performed on the source and drain metal layer to form the source and the drain.

Based upon the same inventive idea, some embodiments of the disclosure provide a metal induced crystallization fabricated using the method above according to embodiments of the disclosure.

A process of fabricating a metal induced crystallization using the method according to embodiments of the disclosure will be described below in details as follows.

1. A buffer layer 02 is formed on a base substrate 01 through the chemical vapor deposition;

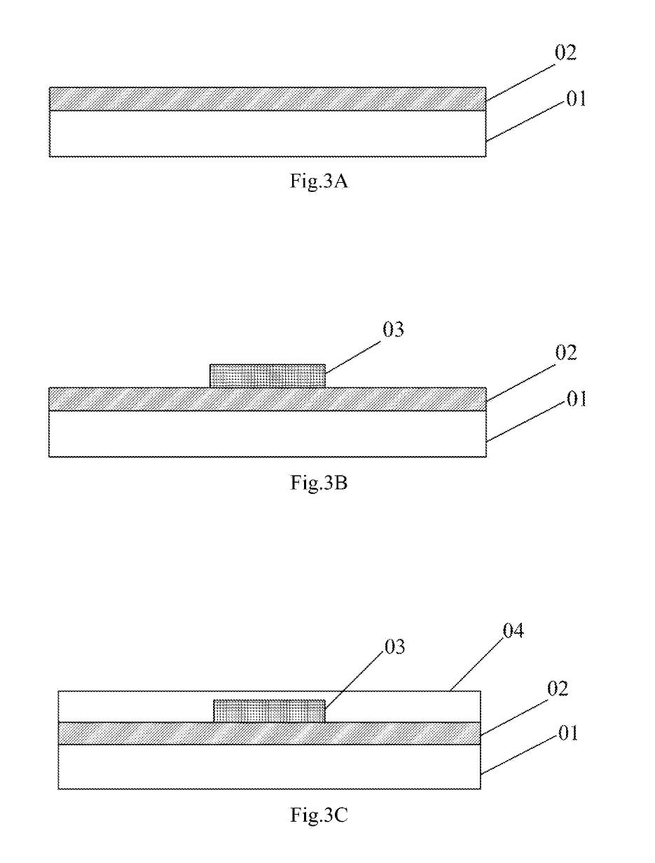

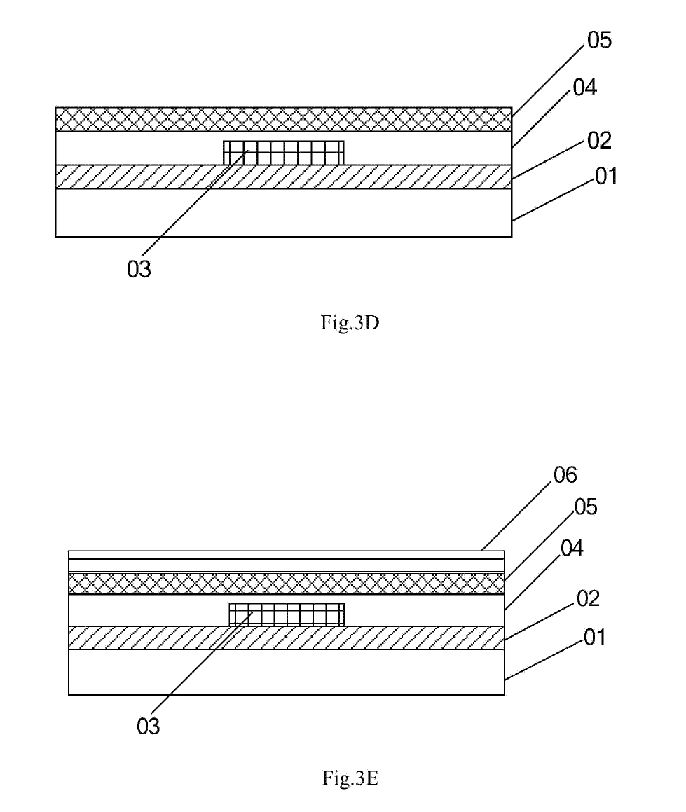

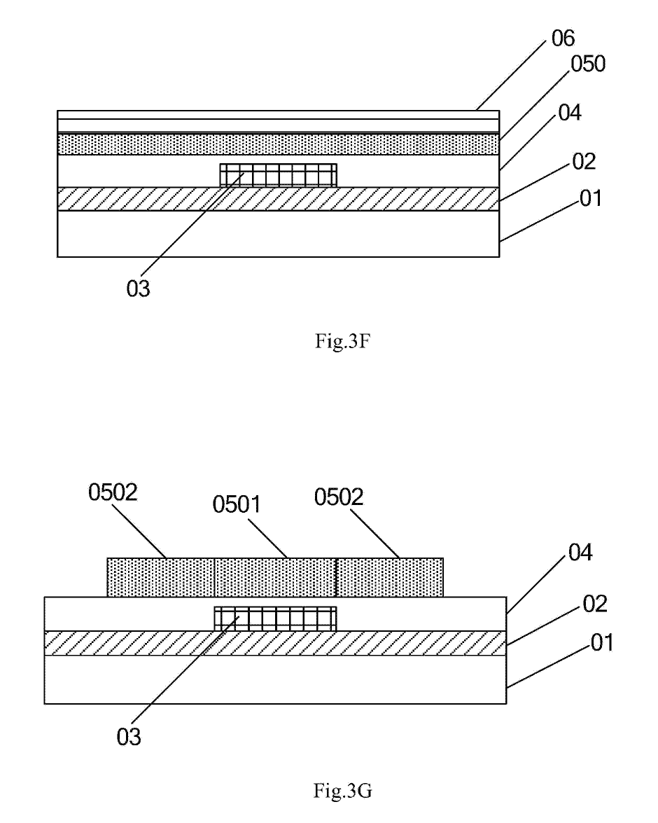

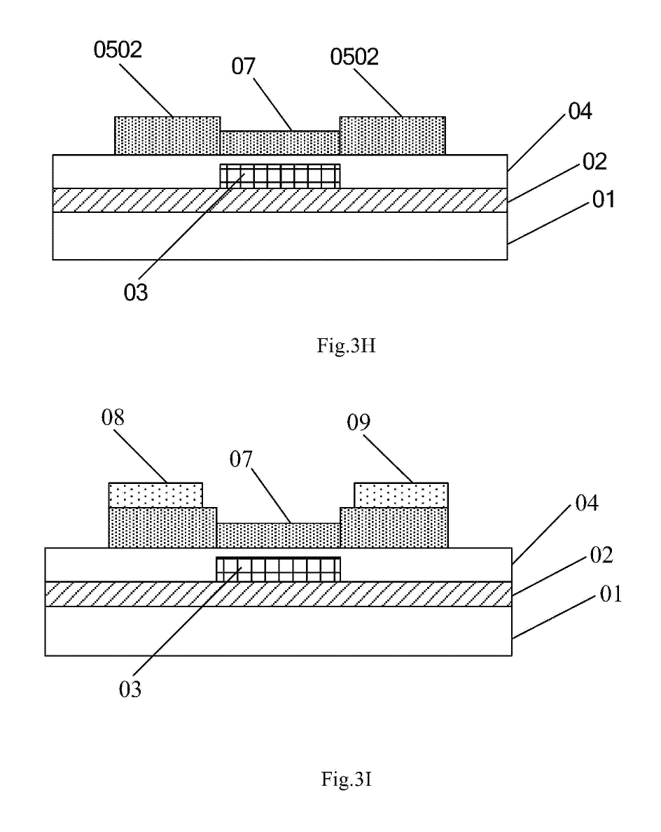

FIG. 3A illustrates the base substrate formed with the buffer layer 02, where the material of the base substrate can be glass, quartz, silicon, an organic polymer, etc., and the material of the buffer layer can be silicon oxide, silicon nitride, or a combination of both;

2. A gate metal layer is deposited on the base substrate formed with the buffer layer 02 through the magnetron sputtering, and a patterning process is performed on the gate metal layer to form a gate 03;

FIG. 3B illustrates the base substrate formed with the gate 03, where the material of the gate can be molybdenum, aluminum, titanium, copper, or gold;

3. A gate insulation layer 04 is deposited on the base substrate formed with the gate 03 through the chemical vapor deposition;

FIG. 3C illustrates the base substrate formed with the gate insulation layer 04, where the material of the e gate insulation layer can be silicon oxide, silicon nitride, or a combination of both, or can be another oxide with good thermal conductivity, e.g., aluminium oxide, and the gate insulation layer can also function as a metal inductive barrier layer for blocking the gate from interacting with the poly-silicon layer in subsequent annealing;

4. An amorphous-silicon layer 05 is formed on the base substrate formed with the gate insulation layer 04 through the chemical vapor deposition. FIG. 3D illustrates the base substrate formed with the amorphous-silicon layer 05;

5. A metal inductive layer 06 is formed on the substrate formed with the amorphous-silicon layer 05. FIG. 3E illustrates the base substrate formed with the metal inductive layer 06;

6. Annealing is performed on the base substrate formed with the metal inductive layer 06;

The amorphous-silicon layer 05 after annealing is converted into a poly-silicon layer 050. FIG. 3F illustrates the annealed base substrate;

7. A patterning process is performed on the annealed base substrate to form a first doped zone 0501 corresponding to the active layer, and a second doped zone 052 corresponding to the source and the drain. FIG. 3G illustrates the base substrate formed with the first doped zone 0501 and the second doped zone 0502;

8. The formed first doped zone 0501 is etched to form a pattern of an active layer 07. FIG. 3H illustrates the base substrate formed with the active layer 07;

9. Patterns of a corresponding source 08 and drain 09 are formed in the formed second doped zone 0502. FIG. 3I illustrates the base substrate formed with the source 08 and the drain 09.

Some embodiments of the disclosure provide a thin film transistor and a method for fabricating the same, where the method for fabricating a thin film transistor includes: forming a buffer layer, a gate, and a pattern of a gate insulation layer on a base substrate successively; further includes: forming an amorphous-silicon layer on the base substrate formed with the pattern of the gate insulation layer; forming a metal inductive layer on the base substrate formed with the amorphous-silicon layer; performing annealing on the base substrate formed with the metal inductive layer; performing a patterning process on the annealed base substrate to form a first doped zone corresponding to the active layer, and a second doped zone corresponding to a source and a drain; etching the formed first doped zone to form a pattern of the active layer; and forming patterns of the corresponding source and drain in the formed second doped zone.

Optionally in the method for fabricating a thin film transistor according to embodiments of the disclosure, annealing can be performed on the base substrate formed with the metal inductive layer to thereby perform metal induced crystallization so as to fabricate the low-temperature poly-silicon thin film transistor with the bottom gate while dispensing with a shielding layer in a top-gate thin film transistor, thus saving the fabrication cost, simplifying the fabrication process, and dispensing with the step of doping the poly-silicon material due to metal induced crystallization. Furthermore the amorphous-silicon can be converted into the poly-silicon due to metal induced crystallization, and the patterning process can be further performed on the poly-silicon layer to form the first doped zone corresponding to the active layer, and the second doped zone corresponding to a source and drain area, so that a channel area can be separated from the source and drain area to thereby guarantee the electrical performance of the thin film transistor; and furthermore the first doped zone can be etched to thereby remove metal particles remaining in the channel area due to metal induced crystallization so as to reduce the off-stage current in the device, thus addressing the problem of the remaining metal particles, and guaranteeing the good electrical performance of the device.

Evidently those skilled in the art can make various modifications and variations to the disclosure without departing from the spirit and scope of the disclosure. Accordingly the disclosure is also intended to encompass these modifications and variations thereto so long as the modifications and variations come into the scope of the claims appended to the disclosure and their equivalents.

1. A method for fabricating a thin film transistor, the method comprises: forming a buffer layer, a gate, and a pattern of a gate insulation layer on a base substrate successively, wherein the method further comprises:
forming an amorphous-silicon layer on the base substrate formed with the pattern of the gate insulation layer;
forming a metal inductive layer on the base substrate formed with the amorphous-silicon layer;
performing annealing on the base substrate formed with the metal inductive layer;
performing a patterning process on annealed base substrate to form a first doped zone corresponding to an active layer, and a second doped zone corresponding to a source and a drain;
etching the first doped zone to form a pattern of the active layer; and
forming patterns of the source and the drain in the second doped zone.

2. The method according to claim 1, wherein the performing annealing on the base substrate formed with the metal inductive layer comprises:
heating the base substrate formed with the metal inductive layer at a preset temperature in a protective gas or vacuum atmosphere for a preset length of time, and thereafter cooling the base substrate naturally to an indoor temperature.

3. The method according to claim 2, wherein the preset temperature ranges from 400 to 600° C., and the preset length of time ranges from 10 to 20 minutes.

4. The method according to claim 1, wherein the forming the metal inductive layer on the base substrate formed with the amorphous-silicon layer comprises:
forming the metal inductive layer on the base substrate formed with the amorphous-silicon layer through a magnetron sputtering.

5. The method according to claim 2, wherein the forming the metal inductive layer on the base substrate formed with the amorphous-silicon layer comprises:
forming the metal inductive layer on the base substrate formed with the amorphous-silicon layer through a magnetron sputtering.

6. The method according to claim 3, wherein the forming the metal inductive layer on the base substrate formed with the amorphous-silicon layer comprises:
forming the metal inductive layer on the base substrate formed with the amorphous-silicon layer through a magnetron sputtering.

7. The method according to claim 1, wherein the material of the metal inductive layer is one or a combination of aluminum, copper, nickel, gold, silver, and molybdenum.

8. The method according to claim 1, wherein the etching the first doped zone to form the pattern of the active layer comprises:
etching off a peak layer on a surface of the first doped zone to form the pattern of the active layer, wherein the peak layer is a metal layer doped on the surface of the first doped zone at a dosage of metal ions above a preset threshold; and an orthographic projection of the active layer onto the base substrate overlaps with an orthographic projection of the gate onto the base substrate.

9. The method according to claim 1, wherein the forming the patterns of the source and the drain in the second doped zone comprises:
deposing a source and drain metal layer on the base substrate formed with the second doped zone through a magnetron sputtering; and
performing a patterning process on the source and drain metal layer to form the patterns of the source and the drain.

10. The method according to claim 9, wherein the source is structured in a stack of titanium-aluminum-titanium layers or molybdenum-aluminum-molybdenum layers; and the drain is structured in a stack of titanium-aluminum-titanium layers or molybdenum-aluminum-molybdenum layers.

11. A thin film transistor, comprising: a buffer layer, a gate, and a pattern of a gate insulation layer which are formed successively on a base substrate, wherein the thin film transistor further comprises:
an amorphous-silicon layer formed on the base substrate formed with the pattern of the gate insulation layer;
a metal inductive layer formed on the base substrate formed with the amorphous-silicon layer;
a first doped zone corresponding to an active layer, and a second doped zone corresponding to a source and a drain;
a pattern of the active layer formed by etching the first doped zone; and
patterns of the source and the drain formed in the second doped zone;
wherein the first doped zone and the second doped zone are formed by performing annealing on the base substrate formed with the metal inductive layer and performing a patterning process on annealed base substrate.

12. The thin film transistor according to claim 11, wherein the performing annealing on the base substrate formed with the metal inductive layer comprises:
heating the base substrate formed with the metal inductive layer at a preset temperature in a protective gas or vacuum atmosphere for a preset length of time, and thereafter cooling the base substrate naturally to an indoor temperature.

13. The thin film transistor according to claim 12, wherein the preset temperature ranges from 400 to 600° C., and the preset length of time ranges from 10 to 20 minutes.

14. The thin film transistor according to claim 11, wherein the metal inductive layer is formed on the base substrate formed with the amorphous-silicon layer by:
forming the metal inductive layer on the base substrate formed with the amorphous-silicon layer through a magnetron sputtering.

15. The thin film transistor according to claim 12, wherein the metal inductive layer is formed on the base substrate formed with the amorphous-silicon layer by:
forming the metal inductive layer on the base substrate formed with the amorphous-silicon layer through a magnetron sputtering.

16. The thin film transistor according to claim 13, wherein the metal inductive layer is formed on the base substrate formed with the amorphous-silicon layer by:
forming the metal inductive layer on the base substrate formed with the amorphous-silicon layer through a magnetron sputtering.

17. The thin film transistor according to claim 11, wherein the material of the metal inductive layer is one or a combination of aluminum, copper, nickel, gold, silver, and molybdenum.

18. The thin film transistor according to claim 11, wherein the pattern of the active layer is formed by etching the first doped zone in following manner:
etching off a peak layer on a surface of the first doped zone to form the pattern of the active layer, wherein the peak layer is a metal layer doped on the surface of the first doped zone at a dosage of metal ions above a preset threshold; and an orthographic projection of the active layer onto the base substrate overlaps with an orthographic projection of the gate onto the base substrate.

19. The thin film transistor according to claim 11, wherein the patterns of the source and the drain are formed in the second doped zone in following manner:
deposing a source and drain metal layer on the base substrate formed with the second doped zone through a magnetron sputtering; and
performing a patterning process on the source and drain metal layer to form the patterns of the source and the drain.

20. The thin film transistor according to claim 19, wherein the source is structured in a stack of titanium-aluminum-titanium layers or molybdenum-aluminum-molybdenum layers; and the drain is structured in a stack of titanium-aluminum-titanium layers or molybdenum-aluminum-molybdenum layers.
